(19) United States
(12) Patent Application Publication
(10) Pub. No.: US 2015/0007881 A1
(43) Pub. Date: Jan. 8, 2015

(54) ALUMINUM CONDUCTOR PASTE FOR BACK SURFACE PASSIVATED CELLS WITH LOCALLY OPENED VIAS

(71) Applicant: Heraeus Precious Metals North America Conshohocken LLC, West Conshohocken, PA (US)

(72) Inventors: Chandrashekhar S Khadilkar, Broadview Heights, OH (US); Himal Khatri, San Diego, CA (US); Srinivasan Sridharan, Strongsville, OH (US); George E. Graddy, JR., Del Mar, CA (US); Aziz S. Shaikh, San Siego, CA (US); Nazarali Merchant, Fremont, CA (US)

(21) Appl. No.: 14/371,923

(22) PCT Filed: Jan. 11, 2013
(86) PCT No.: PCT/US2013/021109

§ 371 Date: Jul. 11, 2014

Related U.S. Application Data
(60) Provisional application No. 61/587,068, filed on Jan. 16, 2012.

(51) Int. Cl. H01L 31/0224; H01L 31/02; H01L 31/0216

(52) U.S. Cl. CPC H01L 31/022425; H01L 31/02167; H01L 31/02008
USPC 136/256; 252/512; 438/98

(57) ABSTRACT

This invention relates an aluminum conductor paste formulation and its method of application on rear side passivated locally opened vias; dot or line geometry or combination thereof employing laser ablation or chemical etching methods. Such Back Surface Passivated Si-solar cells include dielectric layers of Al203, SiNx, Si02, SiC, α-Si, Si02/SiNx, Al203/SiNx, Si02/Al203/SiNx. The Al-conductor paste of this invention achieves; (i) non-degradation of passivation stack, (ii) defect free surfaces and void free vias, (iii) a strong and uniform Back Surface Field (BSF) layer within dot vias and line vias.

### TECHNICAL FIELD

The subject disclosure generally relates to paste compositions, methods of making a paste composition, photovoltaic cells, and methods of making a photovoltaic cell contact.

### BACKGROUND

Solar cells are generally made of semiconductor materials, such as Silicon (Si), Cadmium Telluride (CdTe), Copper Indium Gallium Selenium (CIGSe) etc. which convert sunlight into useful electrical energy. Si solar cells are typically made of wafers of Si in which the required PN junction is formed by diffusing phosphorus (P) from a suitable phosphorus source into a P-type Si wafer. The side of silicon wafer on which sunlight is incident is in general coated with silicon nitride layer as an anti-reflective coating (ARC) with excellent surface and bulk passivation properties to prevent reflective loss of incoming sunlight and recombination loss, respectively and thus to increase the efficiency of the solar cell. A two dimensional electrode grid pattern known as a front contact makes a connection to the N-side of silicon, and a coating of aluminum (Al) on the other side (back contact) makes connection to the P-side of the silicon. These contacts are the electrical outlets from the PN junction to the outside load.

Front and back contacts of silicon solar cells are typically formed by screen-printing a thick film conductor paste. Typically, the front contact paste contains fine silver particles, glass particles, and an organic vehicle. After screen-printing, the wafer and paste are fired in air, typically at infra-red (IR) furnace peak set temperatures of about 650-1000° C. During the firing, glass softens, melts, and reacts and etches the anti-reflective coating, and facilitates the formation of intimate silicon-silver contact. Silver deposits on silicon as islands. The shape, size, number and distribution of silicon-silver islands determine the efficiency of photo-generated electron transfer from silicon to the outside circuit.

Conventional Si-solar cell design includes full Al metallization on the back surface of silicon wafer which is fired along with the front contact silver paste (“co-fired”) in the furnace temperature setting at 600-1000° C., with 120-300 inch per minute (ipm) belt speeds. This generally causes melting of Al, Al—Si reaction and formation of eutectic layer and a back surface field (BSF) layer, contributing to high open-circuit voltage (Voc), high short-circuit current (Isc) and high cell efficiency (η). The BSF formed provides a reasonable back surface passivation and acts as an optical and electrical reflection layer. One drawback of this technology is that the BSF formed is not uniform across the entire back wafer surface and its layer thickness, and extent of Al doping is a function of the paste chemistry, nature of silicon wafer (single or poly crystal), type of surface texture, wafer thickness and size, and firing conditions, among other factors. Moreover, due to co-firing of the front silver and back Al pastes, the firing conditions are more dictated by the front silver composition and the wafer properties (such as total phosphorus concentration phosphorus doping profile, etc., as measured by sheet resistivity and pn junction depth, than by the back Al paste. This produces considerable variability in electrical performance which has direct impact on Voc, Isc and the cell efficiency. Furthermore, full Al paste printing with a strong reaction with Si surface causes wafer warpage (bowing), thus, limiting the use of thinner wafers and increases in the solar module manufacturing yield losses.

In conventional Si solar cells with no back surface dielectric passivation, Al conductor paste is applied on back surface (P-side) of crystalline silicon solar wafer, which on firing, forms Al—Si eutectic alloy along with Back Surface Field (BSF) that gives good electrical performance. The BSF layer provides good Ohmic contacts, reasonable passivation on the back side of the cell and optical and electronic reflection, thus enhancing open circuit voltage (Voc) and short circuit current (Isc), determine the efficiency of cells. However, to improve the energy conversion efficiency, a process scheme that incorporates a high quality back surface passivation and provides a good optical confinement is needed, especially if the cell thickness is reduced. In advanced cell designs, the back surface passivation is provided by dielectric stack consisting of Al₂O₃, SiNx, SiO₂/SiNx, SiC, α-Si or Al₂O₃/SiNx or SiO₂/Al₂O₃/SiNx stack having a thickness in the 5-360 nm range. The advantages of rear side passivation are twofold: (i). the passivation dielectric layer reduces the surface recombination of minority carriers at the rear surface, and (ii). the presence of a dielectric layer enhances the internal reflectivity at the rear surface, allowing more light to be reflected back into the cell. Therefore, rear passivated solar cells exhibit higher short circuit currents (Isc) and open circuit voltages (Voc) resulting in higher conversion efficiencies in comparison to back unpassivated conventional Si-solar cells.

A passivated rear surface requires patterned local contacts to silicon through the dielectric film. Two different techniques can be employed for the fabrication of rear point contacts. One approach is to locally open the passivation layer followed by full area screen printing of aluminum paste and subsequent thermal alloying to form contacts. The other method is full area screen printing of aluminum paste on passivation layer followed by laser firing through the dielectric layer to form local contact. In both cases the intact region of the passivation layer protects the silicon surface and maintains the passivation quality. During these processes, underneath the alloyed local contact points, a thin aluminum doped silicon layer known as local back surface field (Al-BSF) is formed. This Al-BSF layer repels the minority carriers reducing the surface recombination. There are several important factors which affect the formation of defect free robust local contacts. The nature of the passivation film stack, the geometry of the local contact pattern, the chemical composition of the aluminum paste and the firing parameters of the alloying process all strongly contribute to forming a defect (void)-free local contact. For a given passivation film stack with fixed contact pattern and firing profile the extent of voids free local contacts formation substantially varies from one paste formulation to another. In formulating a screen printable aluminum paste for rear local contact application several factors should be taken into consideration. The paste should have a low contact resistance to silicon and a low bulk resistivity to allow for the cell to function in a soldered string with minimum series resistance losses. Also, the fired paste must strongly adhere to the passivation dielectric layer so that the integrity of the passivation quality is maintained after contact formation. Furthermore, paste composition should be such that it should be able to form voids free contact formation in the presence of a sufficiently thick and uniform BSF layer over a range of contact sizes with different firing conditions. This invention describes paste formulations for back surface passivated cells with locally opened vias and method of application of this paste in order to achieve this goal.

### SUMMARY

The following presents a simplified summary of the invention in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

In accordance with one aspect, a paste composition is provided. More particularly, in accordance with this aspect, the paste composition includes one or more conductive metal components, a glass component, and a vehicle. The paste may further include organic and/or inorganic additives.

In accordance with another aspect, a photovoltaic cell structure is provided. More particularly, in accordance with this aspect, the photovoltaic cell includes a silicon wafer and a back contact thereon, the back contact including locally opened dielectric passivation stack fully coated with a back side Al paste. The back side paste includes, prior to firing, one or more conductive metal components, one or more glass frits, organic and inorganic additives, and vehicles.

In accordance with yet another aspect, a method of making a paste composition is provided. More particularly, in accordance with this aspect, the method involves mixing and dispersing a conductive metal components, non-leaded glass frits, organic or inorganic additives, and vehicle.

In accordance with still yet another aspect, a method of forming a photovoltaic cell contact is provided. More particularly, in accordance with this aspect, the method involves providing a silicon substrate, dielectric passivation stack and laser/chemical opened passivation exposing the Si-surface thereon; applying a paste composition on the full passivation layer, the paste including a conductive metal components, one or more glass frits, organic and inorganic additives, and vehicles; and heating the paste to sinter the conductive metal component and fuse the glass. The conductive metal component forming a strong and uniform local BSF by reacting with silicon substrate within locally opened vias without any physical defects (voids and other defects), thereby electrically contacting the silicon substrate. The paste provides; good wettability inside small vias, adequate fired adhesion on passivation layer without damaging the superior passivation properties.

To the accomplishment of the foregoing and related ends, the invention, then, involves the features hereinafter fully described and particularly pointed out in the claims. The following description and the annexed drawings set forth in detail certain illustrative embodiments of the invention. These embodiments are indicative, however, of but a few of the various ways in which the principles of the invention can be employed. Other objects, advantages and novel features of the invention will become apparent from the following detailed description of the invention when considered in conjunction with the drawings.

### BRIEF DESCRIPTION OF THE DRAWINGS

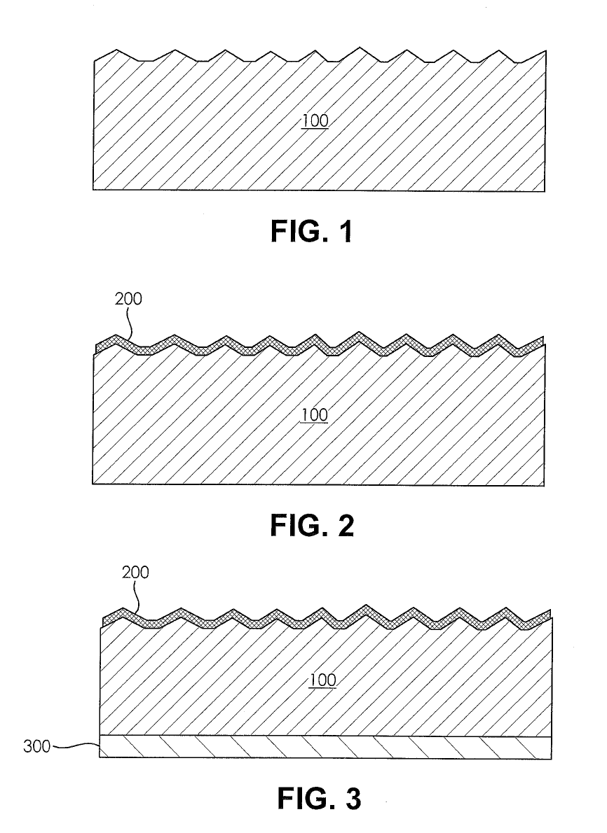

FIGS. 1-7 provide a process flow diagram schematically illustrating the fabrication of a semiconductor solar device. Reference numerals shown in FIGS. 1-7 are explained below.
100: p-type silicon substrate
200: n-type diffusion layer on texturized substrate
300: back side passivation layer (e.g., AlOx, TiO₂, SiO₂. SiC, α-Si or combinations)
400: front side passivation/anti-reflection layer (e.g., SiN_{X}, TiO₂, SiO₂ film)
402: back side passivation/capping layer (e.g., SiN_{X}, TiO₂, SiO₂ film)
500: dielectric passivation opening by laser/chemical etching
600: silver or silver/aluminum back paste formed on backside
602: aluminum back paste formed on backside
604: silver paste formed on front side
700: silver or silver/aluminum back electrode (obtained by firing silver or silver/aluminum back paste)
702: aluminum back electrode after firing showing non-fire through of passivation layer
704: p+ layer (back surface field, BSF) in opened vias
706: silver front electrode after firing through ARC

### DETAILED DESCRIPTION

In Back Surface Passivated (BSP) cells with locally opened vias, the silicon passivation function of the full layer Al BSF is performed by the dielectric layers that include SiNx, SiO₂, Al₂O₃, SiC, α-Si, SiO₂/SiNx, Al₂O₃/SiNx, SiO₂/Al₂O₃/SiNx etc., that have a thickness of 5-360 nm. More recently, single dielectric layer of atomic layer deposited (ALD) Al₂O₃ to a thickness of 5-60 nm thickness has shown to be more effective in back passivation compared to the stack of SiO₂/SiNx or Al₂O₃/SiNx. In order to derive the benefit of superior back passivation from these advanced cell designs, electrical local contact is needed on the back surface since the alloying of Al and Si is prevented by the presence of the dielectric layer(s). One effective method of making this contact is to make laser or chemical openings of various diameters and pitches in the dielectric stack, and then to apply an Al paste to the entire wafer surface, which will form a uniform and strong local Back Surface Field (BSF) in the opened vias, during co-firing steps, without chemically etching or degrading the dielectric stack. In this invention, we describe an Al paste that can achieve this goal. The paste has adequate fired adhesion on above-mentioned passivation layer, have good wettability inside small vias, and have controlled reactivity with the Si within the via so as to form good local BSF with few or no imperfections. The invention includes such an inventive paste and its method of application in BSP cells with locally opened vias.

The subject invention can overcome the shortcomings of the conventional methods of making back contacts. The subject invention generally relates to paste compositions, photovoltaic cells including fired paste compositions, methods of making a paste composition, and methods of making a photovoltaic cell. The paste compositions can be used to form a contact to solar cells and, other related components. The subject invention can provide one or more of the following advantages: (1) photovoltaic cells with an excellent back passivation due to dielectric layer AlOx, SiO₂, SiC, α-Si, SiNx, SiO₂/SiNx, AlOx/SiO₂/SiNx; (2) novelty of Al paste that does not degrade the passivation and thus the passivation of the dielectric remains effective; (3) BSF formation and/or Al—Si eutectic formation is uniform and fully developed within the vias; and therefore (4) there are no wide variations in the efficiency of cells achieved.

The paste composition can include one or more conductive metal components, one or more glass frits, organic and inorganic additives, and vehicles. Metals of interest include Boron, Gallium, Indium, Titanium and combination thereof, which may be obtained from 0 M Group, Cleveland, Ohio. Non-limiting examples include: Borate esters such as trimethyl borate, triethylborate, (Borosilica Film) (CxHyO, x=1-9, Y=2x+1) and Alkoxides of Titanium (Ti-Ethoxides, Ti propoxides, Ti butoxides, Ti pentoxides, Ti aryloxides etc.), Alkoxides of Zirconia etc. Paste can include Organo metallic compounds such as but not limited to Ni, Co, Zn and V. For example, metal carboxylates such as Ni-Hex Cem, Cur-Rex etc., acetonates of Cu, Ni etc.

The paste composition should have a low contact resistance to silicon and a low bulk resistivity to allow the cell to function in a soldered string with minimum series resistance losses. Also, the paste must strongly adhere to the passivation dielectric layer so that the integrity of the passivation quality is maintained after contact formation. Furthermore, paste composition should be such that it should enable to form voids free contacts with sufficiently thick BSF layer over a range of contact sizes with different firing conditions. The dielectric passivation can include any or all of SiNx, Al₂O₃, SiO₂, SiC, α-Si, TiO₂, Al₂O₃/SiNx, or SiO₂/Al₂O₃/SiNx deposited using various methods such as plasma enhanced chemically vapor deposition (PECVD), plasma assisted atomic layer deposition (ALD), induced coupled plasma deposition (ICPD), thermal oxidation etc.

Paste formulations are generally screen printable and suitable for use in photovoltaic devices. However, other application procedures can be used such as spraying, hot melt printing, pad printing, ink jet printing, and tape lamination techniques with suitable modifications of the vehicle component.

The pastes herein can be used to form conductors in applications other than solar cells, and employing other substrates, such as, for example, glass, ceramics, enamels, alumina, and metal core substrates. For example, the paste is used in devices including MCS heaters, LED lighting, thick film hybrids, fuel cell systems, automotive electronics, and automotive windshield busbars.

The pastes can be prepared either by mixing individual components (i.e., metals, glass frits, organic/inorganic compounds, and vehicles) or by blending pastes that are Al based (major component) with organic/inorganic additives that achieve the desired objectives. Broadly construed, the inventive pastes include a conductive metal including at least aluminum, glass, organic/inorganic additives, and a vehicle. Each ingredient is detailed hereinbelow.

Metal Component.

The conductive metal component can include aluminum. In one embodiment, the major metal component of the paste is aluminum. Aluminum is used because it forms a low contact resistance p+/p surface on p-type silicon and provides a BSF for enhancing solar cell performance. In one embodiment, the backside pastes of the invention include about 40 to about 80 wt % aluminum, preferably about 60 to about 80 wt % aluminum and more preferably about 65 to about 75 wt % aluminum. The conductive metal component can include aluminum alloys, aluminum silicon alloys and mixtures of aluminum metal and aluminum alloys.

The paste can also include other metals and/or alloys to preserve the dielectric passivation layer. The other metals and alloys can include any suitable conductive metal(s) other than aluminum. In one embodiment, the other metals and/or alloying elements can be at least one other metal selected from the group consisting of palladium, silver, platinum, gold, boron, gallium, indium, zinc, tin, antimony, magnesium, potassium, titanium, vanadium, nickel, and copper.

The conductive metal component can include the other metals or alloys at any suitable amount so long as the other metals or alloys can aid in achieving optimum contact to silicon without adversely affecting the passivation layer. In one embodiment, the conductive metal component includes about 0.1 to about 50 wt % the other metals or alloys. In another embodiment, the metal component includes about 0.5 to about 50 wt %, 1 to about 25 wt %, more preferably about 2 to about 10 wt % of silver. In yet another embodiment, the metal component includes about 3 to about 50 wt %, preferably about 3 to about 15 wt %, more preferably about 3 to about 10 wt % copper. In still yet another embodiment, the metal component includes about 1 to about 50 wt %, preferably about 5 to about 25 wt %, and more preferably about 5 to about 15 wt % nickel. Contacts and solar cells including the above metals are envisioned herein. Combinations of the foregoing metals are envisioned.

The conductive metal component can have any suitable form. The particles of the conductive metal component can be spherical, flaked, colloidal, amorphous, or combinations thereof. In one embodiment, the conductive metal component can be coated with various materials such as phosphorus. Alternately, the conductive metal component can be coated on glass.

The conductive metal component can have any suitable size particle. Generally, the sizes of the conductive metal component particles are about 0.1 to about 40 microns, preferably about 0.1 to about 10 microns. In one embodiment, the Al particles are generally about 2 to about 20 microns, preferably, about 3 to about 10 microns. In another embodiment, the other metal particles are about 2 to about 20 microns, more preferably about 2 to about 8 microns. In one embodiment the metal particles may have a bimodal particle size distribution such as one mode in the range of 0.5-3.0 microns and the other mode in the range of 3.0-40 microns, where no overlap is intended. In yet another embodiment, the metal particle sizes are in line with the sizes of aluminum and silver particles herein, in a back contact. In still yet another embodiment, Al and other metals/alloys have 99+% purity.

In one embodiment, the metal component include about 80 to about 99 wt % spherical metal particles or alternatively about 35 to about 70 wt % metal particles and about 29 to about 55 wt % metal flakes. In another embodiment, the metal component includes about 75 to about 90 wt % metal flakes and about 5 to about 9 wt % of colloidal metal, or about 60 to about 95 wt % of metal powder or flakes and about 4 to about 20 wt % of colloidal metal. The foregoing combinations of particles, flakes, and colloidal forms of the foregoing metals are not intended to be limiting, where one skilled in the art would know that other combinations are possible. Suitable commercial examples of aluminum particles are available from Alcoa, Inc., Pittsburgh, Pa.; Ampal Inc., Flemington, N.J.; and ECKA Granulate GmbH & Co. KG, of Fürth, Germany.

In one embodiment, the metal component may include other conductive metals from groups such as (a) palladium, silver, platinum, gold, and combinations thereof (highly conductive or electrical conduction modifier); (b) boron, gallium, indium, and combinations thereof (trivalent dopants for P type silicon); (c) zinc, tin, antimony, and combinations thereof (low melting metals); and (d) magnesium, titanium, potassium, vanadium, nickel, copper, and combinations thereof (grain modifiers/refiners). Further alloys such as Al—Cu, Al—Mg, Al—Si, Al—Zn, and Al—Ag, and Ag—Pd, Pt—Au, Ag—Pt, can be used Mixtures of the foregoing metals can also be used for the pastes, contacts, and solar cells herein.

In one embodiment, the conductive metal may further includes up to 20 wt % of at least one selected from the group consisting of an Al—Si eutectic, zinc, tin, antimony, silicon, bismuth, indium, molybdenum, palladium, silver, platinum, gold, titanium, vanadium, nickel, copper, and combinations thereof.

A minimum of one organometallic component is used in the paste formulation.

The organic and organometallic compounds may include boron, gallium, indium, titanium, nickel, cobalt, zinc and vanadium and combination thereof. Examples: Borate esters such as trimethyl borate, triethylborate, (Borosilica Film) (CxHyO, x=1-9, Y=2x+1) and alkoxides of titanium such as Ti-ethoxides, Ti-propoxides, Ti-butoxides, Ti-pentoxides, Ti-aryloxides; alkoxides of zirconia etc. Metal carboxylates such as Hex-Cem and Cur-Rex are suitable as well as acetonates of any named metal, especially Cu, Ni, V, and Zn.

Suitable organometallics include HEX-CEM® (Octoates) from OM Group, Inc., Cleveland, Ohio. Other Hex Cem products include Cobalt Hex-Cem®; Calcium Hex-Cem®; Potassium Hex-Cem®; Manganese Hex-Cem®; Rare Earth Hex-Cem®; Zinc Hex-Cem®; Zirconium Hex-Cem®; Strontium Hex-Cem®. Also suitable are TEN-CEM® Driers which are neodecanoates or versatates. Suitable Ten-Cem products include: Cobalt Ten-Cem®; Calcium Ten-Cem®; Manganese Ten-Cem®; Rare Earth Ten-Cem®; Lithium Ten-Cem®. Also suitable are CEM-ALL®, synthetic acid metal carboxylates such as Cobalt Cem-All®; Calcium Cem-All®; Manganese Cem-All®; Manganese Cem-All® Light-Color; Lead Cem-All®; Zinc Cem-ARC); NAP-ALL® Driers (Naphthenates) such as Cobalt Nap-All®; Calcium Nap-All®; Manganese Nap-All®; Zinc Nap-All and Lead Nap-All®.

Inorganic Oxide Component.

In one embodiment, the inorganic oxide components can be provided in the form of an oxide of the following elements: silicon, palladium, silver, boron, gallium, indium, zinc, tin, antimony, magnesium, potassium, titanium, vanadium, nickel, and copper. Ionic salts, such as halides, carbonates, hydroxides, phosphates, nitrates, sulfates, and sulfites, of the metal of interest which upon decomposition provide oxides of the metal can be also used.

Organometallic Component.

Organometallic compounds of the following elements: boron, titanium, nickel, vanadium, silicon, zinc, tin, antimony, magnesium, potassium, vanadium, nickel, and copper. Organometallic compounds of any of the metals can be used, including acetates, formates, carboxylates, phthalates, isophthalates, terephthalates, fumarates, salicylates, tartrates, gluconates, or chelates such as those with ethylenediamine or ethylenediamine tetraacetic acid (EDTA).

Paste Glasses.

The glass can contain one or more suitable glass frits, for example, 2, 3, 4, or more distinct frit compositions. In one embodiment, the glass used herein is zinc alkali borosilicate glasses. As an initial matter, the glass frits used in the pastes herein can intentionally contain lead and/or cadmium, or they can be devoid of intentionally added lead and/or cadmium. In one embodiment, the glass component comprises substantially to completely lead-free and cadmium-free glass fits as shown in Table 1. The glasses can be partially crystallizing or non-crystallizing. In one embodiment partially crystallizing glasses are preferred. Broad categories of suitable glasses include bismuth-zinc; borosilica, alkali titanate, and leaded-glasses. The details of the composition and manufacture of the glass frits can be found in, for example, commonly-assigned U.S. Patent Application Publication Nos. 2006/0289055 and 2007/0215202, which are hereby incorporated by reference.

TABLE 1
Alkali silicate glasses in mole percent of glass component.

| Oxide (mole %) | 1-1 | 1-2 | 1-3 | 1-4 | 1-5 | 1-6 |
|---|---|---|---|---|---|---|
| ZnO | 0-65 | 5-65 | 7-50 | 10-32 | 0-40 | 0-10 |
| B₂O₃ + Al₂O₃ | 0-55 | 5-55 | 7-40 | 10-25 | 0-25 | 0-10 |
| SiO₂ | 0.5-65 | 10-50 | 10-45 | 10-30 | 15-55 | 10-40 |
| Li₂O + Na₂O + K₂O + | 0.5-45 | 0.5-40 | 5-33 | 10-20 | 15-42 | 15-39 |
| Rb₂O + Cs₂O | | | | | | |
| TiO₂ + ZrO₂ | 0-25 | 0.5-25 | 1-20 | 2-15 | 5-25 | 7-22 |
| V₂O₅ + Ta₂O₅ + Sb₂O₅ + P₂O₅ | 0-20 | 1-15 | 0-15 | 0-10 | 0-15 | 1-9 |
| MgO + CaO + BaO + SrO | 0-20 | 0-15 | 0-13 | 0-10 | 1-10 | 0-10 |
| TeO₂ + Tl₂O + GeO₂ | 0-40 | 0-25 | 0-20 | 0-10 | 0-10 | 0-10 |
| F | 0-25 | 0-20 | 1-10 | 1-15 | 0-10 | 0-8 |

In one embodiment, the glass component includes, prior to firing, Zn glasses. Table 2 below shows some exemplary Zn glasses, both Zn—B, and Zn—B—Si glasses. The oxide constituent amounts for an embodiment need not be limited to those in a single column such as 2-1 to 2-6 and can be chosen from different columns in the table.

TABLE 2
Zn glasses in mole percent of glass component.

| Oxide (mole %) | 2-1 | 2-2 | 2-3 | 2-4 | 2-5 | 2-6 |
|---|---|---|---|---|---|---|
| ZnO | 5-65 | 5-65 | 7-50 | 10-32 | 6-18 | 5-14 |
| SiO₂ | 0-65 | 10-65 | 20-60 | 22-58 | 35-58 | 41-66 |
| B₂O₃ + Al₂O₃ | 5-55 | 5-55 | 7-35 | 10-25 | 11-20 | 7.5-19.4 |
| Li₂O + Na₂O + K₂O + | 0-45 | 0-45 | 2-25 | 1-20 | 11-20 | 11-23 |
| Rb₂O + Cs₂O | | | | | | |
| MgO + CaO + BaO + SrO | 0-20 | 0-20 | 0-15 | 0-10 | 0.1-5 | 0-5 |
| TiO₂ + ZrO₂ | 0-25 | 0-25 | 0-15 | 0.5-15 | 0-10 | 0-10 |
| V₂O₅ + Ta₂O₅ + Sb₂O₅ + P₂O₅ | 0-20 | 0-15 | 0-10 | 0.05-5 | 0.05-3 | 0.01-5 |
| TeO₂ + Tl₂O + GeO₂ | 0-40 | 0-30 | 0-20 | 0-20 | 0-5 | 0-5 |
| F | 0-25 | 0-20 | 0-15 | 0-8 | 0.1-6 | 1-10 |

In still yet another embodiment, the glass component includes, prior to firing, alkali-B—Si glasses. Table 3 below shows some exemplary alkali-B—Si glasses. The oxide constituent amounts for an embodiment need not be limited to those in a single column such as 3-1 to 3-5.

TABLE 3
Alkali-B-Si glasses in mole percent of glass component.

| Ingredient (mole %) | 3-1 | 3-2 | 3-3 | 3-4 | 3-5 |
|---|---|---|---|---|---|
| Li₂O + Na₂O + K₂O | 5-55 | 15-50 | 30-40 | 15-50 | 30-40 |
| TiO₂ + ZrO₂ | 0.5-30 | 0.5-20 | 0.5-15 | 1-10 | 1-5 |
| B₂O₃ + SiO₂ | 5-75 | 25-70 | 30-52 | 25-70 | 30-52 |
| V₂O₅ + Sb₂O₅ + | 0-30 | 0.25-25 | 5-25 | 0.25-25 | 5-25 |
| P₂O₅ + Ta₂O₅ | | | | | |
| MgO + CaO + | 0-20 | 0-15 | 0-10 | 0-15 | 0-10 |
| BaO + SrO | | | | | |
| TeO₂ + Tl₂O + GeO₂ | 0-40 | 0-30 | 0.05-20 | 0-20 | 0-5 |
| F | 0-20 | 0-15 | 5-13 | 0-15 | 5-13 |

In one embodiment, the glass component includes, prior to firing, Bi—Zn—B glasses. Table 4 below shows some exemplary Bi—Zn—B glasses. The oxide constituent amounts for an embodiment need not be limited to those in a single column such as 4-1 to 4-5.

TABLE 4
Bi-Zn-B glasses in mole percent of glass component.

| Oxide (mole %) | 4-1 | 4-2 | 4-3 | 4-4 | 4-5 |
|---|---|---|---|---|---|
| Bi₂O₃ | 25-65 | 30-60 | 32-55 | 35-50 | 37-45 |
| ZnO | 3-60 | 10-50 | 15-45 | 20-40 | 30-40 |
| B₂O₃ | 4-65 | 7-60 | 10-50 | 15-40 | 18-35 |

In another embodiment, the glass component includes, prior to firing, Bi—B—Si glasses. Table 5 below shows some exemplary Bi—B—Si glasses. The oxide constituent amounts for an embodiment need not be limited to those in a single column such as 5-1 to 5-5.

TABLE 5
Bi-B-Si glasses in mole percent of glass component.

| Oxide (mole %) | 5-1 | 5-2 | 5-3 | 5-4 | 5-5 |
|---|---|---|---|---|---|
| Bi₂O₃ | 25-65 | 30-60 | 32-55 | 35-50 | 37-45 |
| B₂O₃ | 4-65 | 7-60 | 10-50 | 15-40 | 18-35 |
| SiO₂ | 5-35 | 5-30 | 5-25 | 5-20 | 5-15 |

In another embodiment, the glass component includes, prior to firing, Bi—Si—V/Zn glasses. Table 6 below shows some exemplary Bi—Si—V/Zn glasses. The oxide constituent amounts for an embodiment need not be limited to those in a single column such as 6-1 to 6-5.

TABLE 6
Bi glasses in mole percent of glass component.

| Oxide (mole %) | 6-1 | 6-2 | 6-3 | 6-4 | 6-5 | 6-6 | 6-7 | 6-8 |
|---|---|---|---|---|---|---|---|---|
| Bi₂O₃ | 5-85 | 15-80 | 20-80 | 30-80 | 40-80 | 30-42 | 39-52 | 0-21 |
| B₂O₃ + SiO₂ | 5-35 | 5-30 | 5-25 | 5-20 | 5-15 | 27-48 | 17-24 | 41-62 |
| ZnO | 0-55 | 0-40 | 0.1-25 | 1-20 | 1-15 | 0-38 | 25-39 | 0-17 |
| V₂O₅ | 0-55 | 0.1-40 | 0.1-25 | 1-20 | 1-15 | 0-5 | 0-12 | 0-12 |
| Li₂O + Na₂O + K₂O + | 0-8 | 0-7 | 0-11 | 0-12 | 14-24 | 14-24 | 1-7 | 1-7 |
| Rb₂O + Cs₂O | | | | | | | | |
| MgO + CaO + BaO + SrO | 0-12 | 0-9 | 0-13 | 0-5 | 0-13 | 0-9 | 0-8 | 26-49 |

In yet another embodiment, the glass component includes, prior to firing, Pb—Al—B—Si glasses. Table 7 below shows some exemplary Pb—Al—B—Si glasses. The oxide constituent amounts for an embodiment need not be limited to those in a single column such as 7-1 to 7-12.

TABLE 7
Pb glasses in mole percent of glass component.

| Oxide (mole %) | 7-1 | 7-2 | 7-3 | 7-4 | 7-5 | 7-6 |
|---|---|---|---|---|---|---|
| PbO | 15-75 | 25-72 | 40-70 | 50-70 | 60-70 | 55-80 |
| B₂O₃ + SiO₂ | 5-38 | 20-38 | 20-38 | 5-30 | 5-15 | 4-13 |
| Al₂O₃ | 0-25 | 0.1-23 | 1-10 | 4-19 | 15-23 | 11-22 |
| ZnO | 0-35 | 5-30 | 1-10 | 5-10 | 0-5 | 0-5 |
| TiO₂ + ZrO₂ + HfO₂ | 0-20 | 0-10 | 0.1-3 | 0.1-3 | 0.1-3 | 0.1-3 |
| V₂O₅ + Sb₂O₅ + P₂O₅ + | 0-25 | 0.05-5 | 0-5 | 0-15 | 0.1-5 | 0-5 |
| Ta₂O₅ + Nb₂O₅ | | | | | | |
| MgO + CaO + BaO + SrO | 0-20 | 0-15 | 0-10 | 0-10 | 0-8 | 0-7 |
| Li₂O + Na₂O + K₂O + | 0-40 | 0-30 | 0-20 | 0-10 | 0-10 | 0-8 |
| Rb₂O + Cs₂O | | | | | | |
| TeO₂ + Tl₂O + GeO₂ | 0-70 | 0-50 | 0-40 | 0-30 | 0-20 | 0-10 |
| F | 0-15 | 0-10 | 0-8 | 0-8 | 0-6 | 0-6 |

TABLE 7a
Further Pb glasses.

| Oxide (mole %) | 7-7 | 7-8 | 7-9 | 7-10 | 7-11 | 7-12 |
|---|---|---|---|---|---|---|
| PbO | 57-77 | 59-71 | 24-38 | 27-36 | 25.5-37 | 28-35 |
| B₂O₃ + SiO₂ | 5-11 | 6-10 | 21-37 | 22.3-33.9 | 22-35 | 23.9-33.2 |
| Al₂O₃ | 13-20 | 14-19 | 5-12 | 6.1-10.7 | 5.7-11.3 | 6.2-10.8 |
| ZnO | 0-25 | 0-31 | 0-17 | 0-13 | 24-36 | 25.2-34.7 |
| TiO₂ + ZrO₂ + HfO₂ | 0.5-2.2 | 0.7-1.9 | 0-3 | 0-8 | 0.1-3 | 0.1-3 |
| V₂O₅ + Sb₂O₅ + P₂O₅ + | 0.8-4 | 1-3.5 | 0.1-3 | 0.3-2.5 | 0.4-2.8 | 0.6-2.5 |
| Ta₂O₅ + Nb₂O₅ | | | | | | |
| MgO + CaO + BaO + SrO | 0-7 | 0-15 | 0-10 | 0-10 | 0-8 | 0-7 |
| Li₂O + Na₂O + K₂O + | 0-6 | 0-30 | 0-20 | 0-10 | 0-10 | 0-8 |
| Rb₂O + Cs₂O | | | | | | |
| TeO₂ + Tl₂O + GeO₂ | 0-70 | 0-50 | 0-40 | 0-30 | 0-20 | 0-10 |
| F | 0-5 | 0-10 | 0-8 | 0-8 | 0-6 | 0-6 |

TABLE 7b
Further Pb Glasses.

| Oxide (mole %) | 7-13 | 7-14 | 7-15 | 7-16 | 7-17 |
|---|---|---|---|---|---|
| PbO | 1-90 | 10-70 | 20-50 | 20-40 | 25-65 |
| V₂O₅ | 1-90 | 10-70 | 25-65 | 45-65 | 20-50 |
| P₂O₅ | 5-80 | 5-80 | 5-40 | 5-25 | 5-40 |

It is also envisioned that glass component can contain additions of predominantly vanadate glasses, phosphate glasses, telluride glasses and germanate glasses to impart specific electrical and reactivity characteristics to the resultant contacts.

It is also envisioned that glass frits of Tables 1 to 7 can contain one or more transition metal oxide, wherein the metal of the transition metal oxide is selected from the group consisting of Mn, Fe, Co, Ni, Cu, Cr, W, Nb, Ta, Hf, Mo, Rh, Ru, Pd and Pt, to provide specific adhesion and/or electrical and/or flow properties to the glass component.

The glass frits can be formed by any suitable techniques. In one embodiment, the glass frits are formed by blending the starting materials (e.g., aforementioned oxides) and melting together at a temperature of about 800 to about 1450° C. for about 40 to 60 minutes to form a molten glass having the desired composition. Depending on the raw materials used, amount of glass being melted, and the type of furnace used these ranges will vary. The molten glass formed can then be suddenly cooled by any suitable technique including water quenching to form a frit. The frit can then be ground using, for example, milling techniques to a fine particle size, from about 0.1 to 25 microns, preferably 0.1 to about 20 microns, more preferably 0.2-10 microns, still more preferably 0.4-3.0 microns, most preferably less than 1.3 microns. It is envisioned that the finer particle sizes such as mean particle size less than 1.2 micron and more preferably less than 1.0 micron, and most preferably less than 0.8 micron are the preferred embodiments for this invention. Alternately the mean particle size can preferably be 1 to about 10 microns, alternatively 2 to about 8 microns, and more preferably 2 to about 6 microns. All particle sizes noted herein are the D₅₀ particle size.

It is also envisioned that the glass component can contain multiple glass frits with different mean particle sizes, each as defined elsewhere herein, and in particular in the preceding paragraph.

The glass frits can have any suitable softening temperature. In one embodiment, the glass frits have glass softening temperatures of about 650° C. or less. In another embodiment, the glass frits have glass softening temperature of about 550° C. or less. In yet another embodiment, the glass frits have glass softening temperature of about 500° C. or less. The glass softening point may be as low as 450° C.

The glass frits can have suitable glass transition temperatures. In one embodiment, the glass transition temperatures range between about 250° C. to about 600° C., preferably between about 300° C. to about 500° C., and most preferably between about 300° C. to about 475° C.

The paste composition can contain any suitable amount of the glass component. In one embodiment, the paste composition contains the glass component at about 0.5 wt % or more and about 15 wt % or less. In another embodiment, the paste composition contains the glass component at about 1 wt % or more and about 10 wt % or less. In yet another embodiment, the paste composition contains the glass component at about 2 wt % or more and about 7 wt % or less. In still yet another embodiment, the paste composition contains the glass component at about 2 wt % or more and about 6 wt % or less.

Although generally avoided for various reasons, substantial additions of Tl₂O or TeO₂ or GeO₂ can be present in these glass compositions to attain lower flow temperatures.

Organometallic Compound

The organometallic compounds useful herein in addition to the foregoing include organo-vanadium compounds, organo-antimony compounds, and organo-yttrium compounds. The organometallic compound is a compound where metal is bound to an organic moiety. For example, the organometallic compound is an organic compound containing metal, carbon, and/or nitrogen in the molecule. Further, in addition to the foregoing metal compounds, a second metal additive selected from the group consisting of an organocobalt compound, an organo-tin compound, an organozirconium compound, an organozinc compound and an organo-lithium compound may be included in the paste composition.

The organometallic compound can include any suitable organic moieties such as those that are C₁-C₅₀ linear or branched, saturated or unsaturated, aliphatic, alicyclic, aromatic, araliphatic, halogenated or otherwise substituted, optionally having one or more heteroatoms such as O, N, S, or Si, and/or including hydrocarbon moieties such as alkyl, alkyloxy, alkylthio, or alkylsilyl moieties.

Specific examples of organometallic compounds include metal alkoxides. However other organometallics can be used. The metal can be selected from boron, silicon, vanadium, antimony, phosphorous, yttrium, titanium, nickel, cobalt, zirconium, zinc, lithium and combinations thereof. It is understood that some authorities consider boron and silicon be metalloids, while phosphorus is a non-metal. For the purposes of this document, and without any intention to attribute foreign properties to them, the term “organometallic” may at times be used to include organoboron compounds, organosilicon compounds and organophosphorus compounds. The alkoxide moiety can have a branched or unbranched alkyl group of, for example, 1 to 50, preferably 1 to 20 carbon atoms. The respective alkoxides envisioned herein include, nickel alkoxides, boron alkoxides, phosphorus alkoxides, silicon alkoxides, vanadium alkoxides, vanadyl alkoxides, antimony alkoxides, yttrium alkoxides, cobaltic alkoxides, cobaltous alkoxides, stannic alkoxides, stannous alkoxides, zirconium alkoxides, zinc alkoxides, titanium alkoxides and lithium alkoxides.

Examples of titanium alkoxides include titanium methoxide, titanium ethoxide, titanium propoxide, and titanium butoxide. Analogous examples can be envisioned for nickel alkoxides, boron alkoxides, phosphorus alkoxides, antimony alkoxides, yttrium alkoxides, cobaltic alkoxides, cobaltous alkoxides, nickel alkoxides, zirconium alkoxides, tin alkoxides, zinc alkoxides and lithium alkoxides can be used.

Other examples of organometallic compounds include metal acetonates and metal acetylacetonates, where the metal can be nickel, boron, phosphorus, vanadium, antimony, yttrium, or combinations thereof. Examples of organo-vanadium compounds include nickel acetylacetonates such as Ni(AcAc)₃ (also called nickel (III) 2,4-pentanedionate) where (AcAc) is an acetyl acetonate (also called 2,4-pentanedionate).

In the same way, antimony acetylacetonate, yttrium acetylacetonate, cobaltic acetylacetonate, cobaltous acetylacetonate, nickel acetylacetonate, zirconium acetylacetonate, dibutyltin acetylacetonate, zinc acetylacetonate and lithium acetylacetonate can be used. For example, antimony 2,4-pentanedionate, yttrium 2,4-pentanedionate, or combinations thereof can be used.

Yet other examples of organometallic compounds include metal 2-methylhexanoates, metal 2-ethylhexanoates, and metal 2-propylhexanoates. Specific examples include boron 2-methylhexanoate, phosphorus 2-methylhexanoate, silicon 2-methylhexanoate, vanadium 2-methylhexanoate, antimony 2-methylhexanoate, yttrium 2-methylhexanoate, cobalt 2-methylhexanoate, nickel 2-methylhexanoate, zirconium 2-methylhexanoate, tin 2-methylhexanoate, zinc 2-methylhexanoate lithium 2-methylhexanoate, boron 2-ethylhexanoate, phosphorus 2-ethylhexanoate, silicon 2-ethylhexanoate, vanadium 2-ethylhexanoate, antimony 2-ethylhexanoate, yttrium 2-ethylhexanoate, cobalt 2-ethylhexanoate, nickel 2-ethylhexanoate, zirconium 2-ethylhexanoate, tin 2-ethylhexanoate, zinc 2-ethylhexanoate, lithium 2-ethylhexanoate, vanadium 2-propylhexanoate, boron 2-propylhexanoate, phosphorus 2-propylhexanoate, silicon 2-propylhexanoate, antimony 2-propylhexanoate, yttrium 2-propylhexanoate, cobalt 2-propylhexanoate, nickel 2-propylhexanoate, zirconium 2-propylhexanoate, tin 2-propylhexanoate, zinc 2-propylhexanoate and lithium 2-propylhexanoate.

Yet other examples of organo-metal compounds include metal carboxylates, where the metal can be nickel, vanadium, zinc, or cobalt or combination thereof. Examples of organo-nickel or organo-vanadium compounds include nickel Hex-Cem or Cur-Rex.

Yet other examples of organometallic compounds include metal acrylates and metal methacrylates, where the metal can be nickel, boron, phosphorus, vanadium, antimony, yttrium, cobalt, nickel, zirconium, tin, zinc or lithium. Acids including boron can be used also to introduce boron into the intermetallic, for example boric acid, H₃BO₃; 2-acetamidopyridine-5-boronic acid, 5-acetyl-2,2-dimethyl-1,3-dioxane-dione; 2-acetylphenylboronic acid; 3-acetylphenylboronic acid; 4-acetylphenylboronic acid; 3-aminocarbonylphenylboronic acid; 4-aminocarbonylphenylboronic acid, 3-amino-4-fluorophenylboronic acid; 4-amino-3-fluorophenylboronic acid, and others commercially available from Boron Molecular, Research Triangle, NC.

Vehicle.

The pastes herein include a vehicle or carrier which is typically a solution of a resin dissolved in a solvent and, frequently, a solvent solution containing both resin and a thixotropic agent. The glass frits can be combined with the vehicle to form a printable paste composition. The vehicle can be selected on the basis of its end use application. In one embodiment, the vehicle adequately suspends the particulates and burn off easily upon firing of the paste on the substrate. Vehicles are typically organic. Examples of solvents used to make organic vehicles include alkyl ester alcohols, terpineols, and dialkyl glycol ethers, pine oils, vegetable oils, mineral oils, low molecular weight petroleum fractions, and the like. In another embodiment, surfactants and/or other film forming modifiers can also be included.

The amount and type of organic vehicles utilized are determined mainly by the final desired formulation viscosity, rheology, fineness of grind of the paste, substrate wettability and the desired wet print thickness. In one embodiment, the paste includes about 15 to about 40 wt % of the vehicle. In another embodiment, the paste includes about 20 to about 35 wt % of the vehicle.

The vehicle typically includes (a) up to 80 wt % organic solvent; (b) up to about 15 wt % of a thermoplastic resin; (c) up to about 4 wt % of a thixotropic agent; and (d) up to about 15 wt % of a wetting agent. The use of more than one solvent, resin, thixotrope, and/or wetting agent is also envisioned. Ethyl cellulose is a commonly used resin. However, resins such as ethyl hydroxyethyl cellulose, wood rosin, mixtures of ethyl cellulose and phenolic resins, polymethacrylates of lower alcohols and the monobutyl ether of ethylene glycol monoacetate can also be used. Solvents having boiling points (1 atm) from about 130° C. to about 350° C. are suitable. Widely used solvents include terpenes such as alpha- or beta-terpineol or higher boiling alcohols such as Dowanol® (diethylene glycol monoethyl ether), or mixtures thereof with other solvents such as butyl Carbitol® (diethylene glycol monobutyl ether); dibutyl Carbitol® (diethylene glycol dibutyl ether), butyl Carbitol® acetate (diethylene glycol monobutyl ether acetate), hexylene glycol, Texanol® (2,2,4-trimethyl-1,3-pentanediol monoisobutyrate), as well as other alcohol esters, kerosene, and dibutyl phthalate.

The vehicle can contain organometallic compounds, for example those based on aluminum, boron, zinc, vanadium, or cobalt, nickel, titanium and combinations thereof, to modify the contact. N-Diffusol® is a stabilized liquid preparation containing an n-type diffusant with a diffusion coefficient similar to that of elemental phosphorus. Various combinations of these and other solvents can be formulated to obtain the desired viscosity and volatility requirements for each application. Other dispersants, surfactants and rheology modifiers, which are commonly used in thick film paste formulations, can be included. Commercial examples of such products include those sold under any of the following trademarks: Texanol® (Eastman Chemical Company, Kingsport, Tenn.); Dowanol® and Carbitol® (Dow Chemical Co., Midland, Mich.); Triton® (Union Carbide Division of Dow Chemical Co., Midland, Mich.), Thixatrol® (Elementis Company, Hightstown N.J.), and Diffusol® (Transene Co. Inc., Danvers, Mass.); Akzo Nobel's Doumeen® TDO (tallowpropylene diamine dioleate) and DisperBYK® 110 or 111 from Byk Chemie GmbH. Disperbyk 110 is a solution of a copolymer with acidic groups having an acid value of 53 mg KOH/g, density of 1.03 @ 20° C. and a flash point of 42° C. Disperbyk 111 is a copolymer with acidic groups having an acid value of 129 mg KOH/g, a density of 1.16 and a flash point over 100° C. A vehicle including oleic acids, DisperBYK 111 and Duomeen TDO is preferred.

Among commonly used organic thixotropic agents is hydrogenated castor oil and derivatives thereof. A thixotrope is not always necessary because the solvent coupled with the shear thinning inherent in any suspension can alone be suitable in this regard. Furthermore, wetting agents can be employed such as fatty acid esters, e.g., N-tallow-1,3-diaminopropane dioleate; N-tallow trimethylene diamine diacetate; N-coco trimethylene diamine, beta diamines; N-oleyl trimethylene diamine; N-tallow trimethylene diamine; N-tallow trimethylene diamine dioleate, and combinations thereof.

Other Additives.

Other inorganic additives can be added to the paste to the extent of about 0.1 to about 30 wt %, preferably about 0.1 to about 10 wt %, alternately from about 2 to about 25 wt % and more preferably about 5 to about 20 wt % based on the weight of the paste prior to firing. Other additives such as clays, fine silicon, silica, or carbon, or combinations thereof can be added to control the reactivity of the aluminum with silicon. Common clays which have been calcined are suitable. Fine particles of low melting metal additives (i.e., elemental metallic additives as distinct from metal oxides) such as Pb, Bi, In, Zn, and Sb, and alloys of each can be added to provide a contact at a lower firing temperature, or to widen the firing window.

A mixture of (a) glasses or (b) crystalline additives and glasses or (c) one or more crystalline additives can be used to formulate a glass component in the desired compositional range. The goal is to improve the solar cell electrical performance. For example, second-phase crystalline ceramic materials such as SiO₂, ZnO, MgO, ZrO₂, TiO₂, Al₂O₃, Bi₂O₃, V₂O₅, MoO₃, WO₃, Co₂O₃, MnO, Sb₂O₃, SnO, Tl₂O, TeO₂, GeO₂ and In₂O₃ and reaction products thereof and combinations thereof can be added to the glass component to adjust contact properties. Ceramic additives include particles such as hectorite, talc, kaolin, attapulgite, bentonite, smectite, quartz, mica, feldspar, albite, orthoclase, anorthite, silica, and combinations thereof. Both crystalline and amorphous silica are suitable.

Paste Preparation.

To prepare the paste compositions of the invention, the necessary frit or frits are ground to a fine powder using conventional techniques including milling. The frit component is then combined with the other components including aluminum. The solids are then mixed with the vehicle and the organic/inorganic additive compounds to form the paste. In one embodiment, the paste can be prepared by a planetary mixer.

The viscosity of the paste can be adjusted as desired. In preparing the paste compositions, the particulate inorganic solids and the phosphorus compound are mixed with a vehicle and dispersed with suitable equipment, such as a planetary mixer, to form a suspension, resulting in a composition for which the viscosity will be in the range of about 50-800 poise (5-80 Pa·s), preferably 50 to about 600 poise (5 to 60 Pa·s), more preferably about 100-500 poise (10-50 Pa·s), yet more preferably 150-400 poise (15-40 Pa·s), Generally, when the back contact is only partially covered with the paste, the viscosity should be higher.

Printing and Firing of the Pastes.

The inventive method of making a solar cell back contact involves providing a silicon substrate and a passivation layer thereon, applying the paste composition on the locally opened passivation layer, followed by full area screen printing of aluminum paste and subsequent thermal alloying to form contacts. In one embodiment, the method further involves making an Ag or Ag/Al back contact by applying an Ag or Ag/Al back contact paste on the back surface of the silicon substrate and heating the Ag or Ag/Al back contact paste. In another embodiment, the method further involves making an Ag front contact by applying an Ag front contact paste on the front surface of the silicon substrate and heating the Ag front contact paste.

The pastes can be applied by any suitable techniques including screen printing, ink jet printing, decal application, spraying, brushing, roller coating or the like. In one embodiment, screen printing is preferred. After application of the paste to a substrate in a desired via pattern, the applied coating is then dried and fired to adhere the paste to the substrate. The firing temperature is generally determined by the frit maturing temperature, and preferably is in a broad temperature range. In one embodiment, solar cells with screen printed aluminum back contacts are fired to relatively low temperatures (550° C. to 850° C. wafer temperature; furnace set temperatures of 650° C. to 1000° C.) to form a low resistance contact between the P-side of a boron doped silicon wafer and an aluminum based paste. In another embodiment, the solar cell printed with the subject Al back contact paste, the Ag back contact paste, and the Ag front contact paste can be simultaneously fired at a suitable temperature, such as about 650-1000° C. furnace set temperature; or about 550-850° C. wafer temperature. During firing, the front side ARC is attacked and corroded by the paste; i.e., “fire-through”; however, the back side Ag or Ag/Al and Al back contact paste strongly adhere to the passivation dielectric layer so that the integrity of the passivation quality is maintained after contact formation. Also during firing as the wafer temperature rises above 660° C. melting of Al starts, Al dissolve Si from the substrate Si. During cooling down, Si rejects from the melt to recrystallize epitaxially building up Al-doped layer (p+), after reaching the eutectic temperature of ˜577° C., the remaining liquid phase solidifies.

A p+ layer is believed to provide a BSF, which in turn increases the solar cell performance. The glass in the Al back contact optimally interacts with both Al and Si without unduly affecting the passivation layer and the formation of an efficient BSF layer. The preferred embodiment for these pastes is non-fire-through the passivation layer such as SiNx while achieving low contact resistance to silicon and a low bulk resistivity to allow for the cell to function in a soldered string with minimum series resistance losses. Also, the paste must strongly adhere to the passivation dielectric layer so that the integrity of the passivation quality is maintained after contact formation. Furthermore, paste composition should be such that it should be able to form voids free contacts in the presence of a sufficiently thick BSF layer over a range of contact sizes with different firing conditions. However these pastes can also be fired on the conventional laser fired (to open up holes in passivation layer) back passivated silicon solar cells too.

Method of Front and Back Contact Production.

Referring now to FIGS. 1-7, one of many exemplary methods of making a solar cell Al back contact according to the present invention is illustrated. In this example, the method involves making an Ag or Ag/Al back contact and an Ag front contact also.

FIG. 1 schematically shows providing a substrate 100 of single-crystal silicon or multicrystalline silicon. The substrate typically has a textured front surface which reduces light reflection. In the case of solar cells, substrates are often used as sliced from ingots which have been formed from pulling or casting processes. Substrate surface damage caused by tools such as a wire saw used for slicing and contamination from the wafer slicing step are typically removed by etching away about 10 to 20 microns of the substrate surface using an aqueous alkali solution such as KOH or NaOH, or using a mixture of HF and HNO₃. The substrate optionally can be washed with a mixture of HCl and H₂O₂ to remove heavy metals such as iron that can adhere to the substrate surface. An antireflective textured surface is sometimes formed thereafter using, for example, an aqueous alkali solution such as aqueous potassium hydroxide or aqueous sodium hydroxide. This gives the substrate, 100, depicted with exaggerated thickness dimensions. The substrate is typically a p-type silicon layer having about 200 microns or less of thickness.

FIG. 2 schematically illustrates that, when a p-type substrate is used, an n-type layer 200 is formed to create a p-n junction. Examples of n-type layers include a phosphorus diffusion layer. The phosphorus diffusion layer can be supplied in any of a variety of suitable forms, including phosphorus oxychloride (POCl₃), and organophosphorus compounds. The phosphorus source can be selectively applied to only one side of the silicon wafer, e.g., a front side of the wafer. The depth of the diffusion layer can be varied by controlling the diffusion temperature and time, is generally about 0.2 to 0.5 microns, and has a sheet resistivity of about 40 to about 120 ohms per square. The phosphorus source can include phosphorus-containing liquid coating material. In one embodiment, phosphosilicate glass (PSG) is applied onto only one surface of the substrate by a process such as spin coating, where diffusion is effected by annealing under suitable conditions.

FIG. 3 schematically illustrates forming back side dielectric passivation layer(s) 300, which also usually serves as an optical reflection layer for low energy photons. The passivation layer typically includes SiN_{X}, TiO₂, SiC, α-SI, or SiO2, Al2O3 or combination thereof. The thickness of passivation layers 300 is about 50 to 3000 Å. The SiNx refractive index may be between 1.8 and 2.8.

The passivation layers 300 can be formed by a variety of procedures including low-pressure CVD, plasma CVD, or thermal CVD, or ALD. When thermal CVD is used to form a SiN_{X} coating, the starting materials are often dichlorosilane (SiCl₂H₂) and ammonia (NH₃) gas, and film formation is carried out at a temperature of at least 700° C. When thermal CVD is used, pyrolysis of the starting gases at the high temperature results in the presence of substantially no hydrogen in the silicon nitride film, giving a substantially stoichiometric compositional ratio between the silicon and the nitrogen, i.e., Si₃N₄.

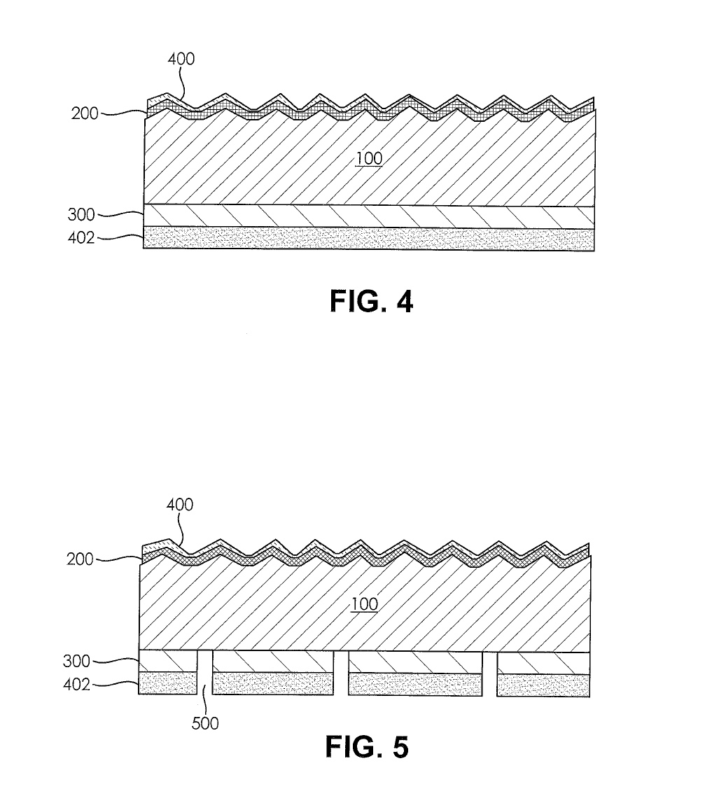

FIG. 4 schematically illustrates passivation layer also on the above-described n-type diffusion layer 200. A back passivation capping layer 402 is similarly applied on the above-described back side passivation layers 300 to the back side of the silicon wafer 100. Silicon nitride is sometimes expressed as SiN_{X}:H to emphasize passivation by hydrogen. The ARC 400 reduces the surface reflectance of the solar cell to incident light, thus increasing the amount of light absorption, and thereby increasing the electrical current generated. The thickness of passivation layers 400 and 402 depends on the refractive index of the material applied, although a thickness of about 500 to 3200 Å is suitable for a refractive index of about 1.9 to 2.0.

FIG. 5 schematically illustrates formation of rear side local openings through dielectric passivation layers 300 and 402 to silicon substrate 100. Optimized local contact openings 500 can be achieved applying an appropriate laser pulse ablation or by an etching process including the screen printing of a phosphorus-containing etching composition or paste. The local contact may have either dot or line geometry or combination thereof. The local contact openings 500 at the rear are separated with 100 to 700 micron for dot geometry and 0.5 mm to 2.0 mm for line geometry. Furthermore, the diameter of the dot and line openings can be from 20 to 200 microns range. If local contact openings are not optimized defects such as Kirkendall voids instead of a eutectic and BSF layer occur due to interactions of two materials with different diffusion rates (DSi>DAl) across the interface.

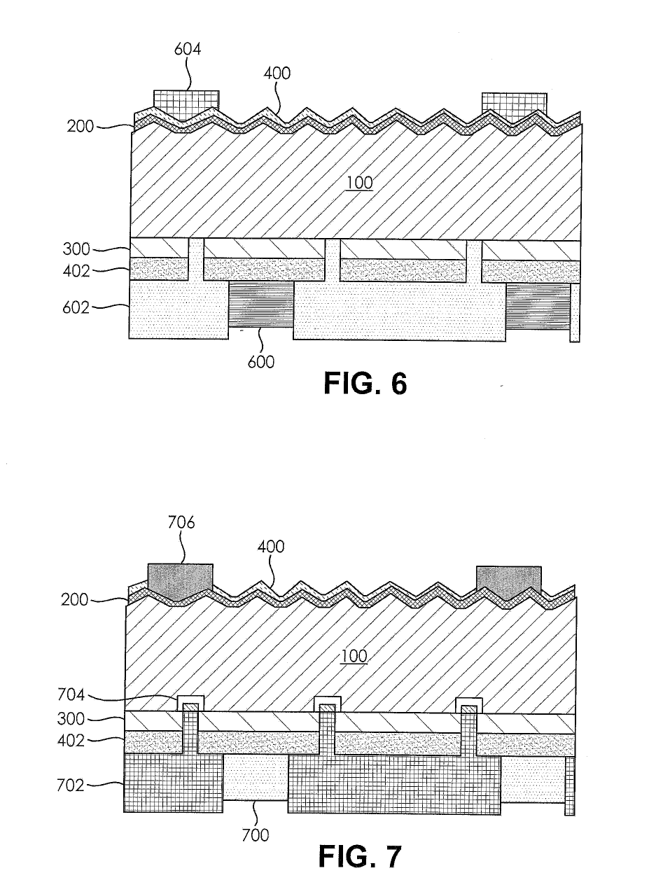

FIG. 6 schematically illustrates applying an Ag or Ag/Al back paste 600 and an Al back paste 602 on the back side of the substrate 100. The preferred Al back paste includes one or more Al powders, organic/inorganic additive compounds herein and one or more glass fits from one or more of Tables 1-7. The pastes can be applied fully, to a wet thickness of about 10 to 50 microns, by screen printing and successively dried on the back side of the substrate. An Ag front paste 604 for a front electrode is next screen printed and dried over the ARC 400. Firing is then carried out in an infrared belt furnace in a temperature range of approximately 700° C. to 1000° C. for a period of from about one to several minutes.

FIG. 7 schematically illustrates forming an Al back contact 702 and forming a BSF layer 704. The Al back paste is transformed by firing from a dried state 602 to an aluminum back contact 702. The Al back paste 602 sinters and forms local BSF layer 704. Aluminum of the Al paste 602 melts and reacts with the silicon substrate 100 through the dielectric openings during firing, then solidifies forming a partial p+ layer, 704, containing a high concentration of aluminum dopant. This layer is generally called the back surface field (BSF) layer, and helps to improve the energy conversion efficiency of the solar cell. The back passivation layer 300 and 400 remains essentially undamaged, that is, unreacted with the aluminum paste during firing in those areas where it was covered by aluminum back paste 602 in FIG. 6. FIG. 7 shows the formation of BSF layer 704 upon co-firing of aluminum paste 602 into three representative local openings in FIG. 6.

The Ag or Ag/Al back paste 600 can be fired at the same time, becoming a Ag or Ag/Al back contact 700. During firing, the boundary between the Al back contact and the Ag or Ag/Al back contact can assume an alloy state, and can be also connected electrically. The back passivation layer 300 and 400 remains essentially undamaged during firing in those areas where it was covered by Ag or Ag/Al back paste 600 in FIG. 6. The Ag or Ag/Al back contact can be used for tab attachment during module fabrication. In addition, the front electrode-forming silver paste 604 sinters and penetrates through (i.e., fires through) the silicon nitride film 400 during firing, and can be thereby able to electrically contact the n-type layer 200, as shown by front electrodes 706 in FIG. 7.

A solar cell back contact according to the present invention can be produced by applying any Al paste disclosed herein, produced by mixing aluminum powders, with the organic or inorganic additive compounds and the glass compositions of Tables 1-7, to the P-side of the silicon substrate, for example by screen printing, to a desired wet thickness, e.g., from about 30 to 50 microns. To make a front contact, front contact Ag pastes can be printed on the front side.

Automatic screen-printing techniques can be employed using a 200-400 mesh screen to apply the Al back paste on the back surface of the substrate. The printed pattern is then dried at about 200° C. or less, preferably at about 120° C. for about 5-15 minutes before firing. The dry printed Al back contact paste of the present invention can be co-fired with the silver rear contact and the front contact silver pastes for as little as 1 second up to about 5 minutes at peak temperature, in a belt conveyor furnace in air.

Nitrogen (N₂) or another inert atmosphere can be used if desired when firing. The firing is generally according to a temperature profile that will allow burnout of the organic matter at about 300° C. to about 550° C., a period of peak furnace set temperature of about 650° C. to about 1000° C., lasting as little as about 1 second, although longer firing times as high as 1, 3, or 5 minutes are possible when firing at lower temperatures. For example a three-zone firing profile can be used, with a belt speed of about 1 to about 4 meters (40-160 inches) per minute. Naturally, firing arrangements having more than 3 zones are envisioned by the present invention, including 4, 5, 6, or 7, zones or more, each with zone lengths of about 5 to about 20 inches and firing temperatures of 650 to 1000° C., for example 660-940° C. In one embodiment, the Al back paste is fired using a typical firing profile of 550° C.-550° C.-550° C.-700° C.-800° C.-940° C. set in a 6-zone furnace with the belt speed of 180 inches per minute.

### Examples

The following examples illustrate the subject invention. Unless otherwise indicated in the following examples and elsewhere in the specification and claims, all parts and percentages are by weight, all temperatures are in degrees Celsius, and pressure is at or near atmospheric pressure.

Exemplary paste compositions, paste groups, average solar cell efficiency and best cell efficiency are shown in Table 8. Twelve pastes tested which were divided into three groups varying glass chemistry, oxide and diffusion controlling additives and the effects of addition of finer aluminum powder. There are no leaded frits in any of these pastes. All these pastes were applied to the passivated pre-opened local vias (dot pattern) by laser ablation as well as to unpassivated substrates and fired under identical conditions. For each, the alumina layer was 20 nm, ALD, formed by induced coupled plasma, and the SiNx layer was deposited by PECVD to a thickness of 80 nm.

The substrates used in this study were 156 mm×156 mm pseudo square, p-type Czochralski solar wafers having a bulk resistivity of 1-5 Ω-cm and had a sheet resistivity of 80-90 ohms per square. The Al back paste is printed on the back passivated side of the wafer, dried and fired. The pastes of Table 2 are fired in a six-zone infrared belt furnace with a belt speed of 200 inches per minute, with temperature settings of 400° C., 400° C., 500° C., for first three zones, and 700° C., 750-820° C., 850-920° C. in last three zones, respectively. The lengths of the zones of the six-zone infrared belt furnace are 45.7, 45.7, 22.9, 22.9, 22.9, and 22.9 cm long, respectively. The details of paste preparation, printing, drying and firing can be found in commonly owned U.S. Patent Application Publication Nos. US2006/0102228 and US 2006/0289055, the disclosures of which are incorporated by reference. More specifically, the fired pastes were evaluated at two different peak set temperatures approximately 880° C. and 900° C. in order to determine the optimal thermal process for local contact formation. The results of the evaluation are shown in Table 8.

The “fill factor” and “efficiency” are measures of the performance of the solar cells. The term “fill factor” is defined as the ratio of maximum power (Vₘₚ×Jₘₚ) divided by the product of short-circuit current density (J_{sc}) and open-circuit voltage (V_{oc}) in current-voltage (I-V) characterization of solar cells. The open circuit-voltage (V_{oc}) is the maximum voltage obtainable under open circuit conditions. The short circuit current density (J_{sc}) is the maximum current density without the load under short-circuits conditions. The “fill factor” (FF), is his defined as (VₘₚJₘₚ)/(V_{oc}J_{sc}), where Jₘₚ and Vₘₚ represent the current density and voltage at the maximum power point. The term “efficiency” is the percentage of power converted (from absorbed light converted to electrical energy) and collected when solar cell is connected to an electrical circuit. Efficiency (η) is calculated using the ratio peak power (Pₘ) divided by the product of total incident irradiance (E, measured in Wm⁻²) and device area (A, measured in m²) under “standard” test conditions where η=Pₘ/(E×A)·In group 1 pastes reactivity increases successively from paste-A to paste-E where the paste-E shows frequent formation of Al-beads on the surface compared to the paste-A. The reactivity of paste-C lies between the paste-B and paste-D and scaled to reaction severity scale 2.5 which is corroborated well with fewer Al-beads on the surface The reaction severity scale 1 means smooth surface while scale 5 means high roughness, in particular due to formation of Al-beads on the surface. Furthermore, the adhesion strength to the substrate of these pastes increases from paste-A to paste-E, where the paste-A has insufficient adhesion (<20N) to the substrate and paste-E provided an excellent adhesion (>40N). Paste-E forms thicker (˜7.6 μm) BSF layer compared to the paste-A which forms ˜6.6 μm thick BSF layer.

The group 2 (paste-F) formulation was targeted for a higher reaction and thus it shows medium Al-beads and produces ˜5.7 μm thick BSF when printed and fired on unpassivated substrates. Also, paste-E shows good adhesion strength (25N) onto Si substrate.

The pastes in group 3 (paste-G and paste-H) were formulated to control the diffusivity of Si atoms into Al matrix through a different formulation chemistry than group 1 and group 2 pastes by using alloyed metal powders. The paste-G (reaction severity rating of 2) has shown smaller but denser Al-beads compared to the paste-H (reaction severity rating of 3). Once printed and fired the paste-G shows a thicker BSF layer (˜7.4 μm) when compared to the paste-H which forms a thinner BSF layer (˜6.7 μm). However, the paste-H has shown complete via fill (no voids at the contact) compared to partial via fill (voids at the contact) by the paste-G. Both pastes have shown adhesion to the substrate in the range of 20-25N. The reduction of voids at the contact due to unequal diffusion rates of Al and Si atoms (D_{Si}>D_{Al}), in the local contacts is a critical requirement to achieve high efficiency cells. For a given local contact geometry, the void formation can be greatly reduced by formulating a paste which (i) controls the out-diffusion of Si atoms into Al matrix, (ii) allows an early saturation of Al—Si melt, and (iii) reductions of an Al—Si mass transfer into Al-matrix, during peak firing process.

TABLE 8
A representative Al paste compositions, and paste properties (bulk resistivity, reaction severity, adhesion to passivation layer and
BSF layer thickness. Table 8 also lists electrical cell performance of rear passivated local contact cells fired at 900 and 880° C.

| | Paste | | | | | | | | | | | |
|---|---|---|---|---|---|---|---|---|---|---|---|---|
| | A | B | C | D | E | F | G | H | I | J | K | L |
| | Group | | | | | | | | | | | |
| | | | | | | | | | 4 | 4 | 4 | 4 |
| | 1 | 1 | 1 | 1 | 1 | 2 | 3 | 3 | Addition of Finer Al Powder & | | | |
| Material | Glass Chemistry | | | | Al—Si Alloy | | | | Organometallic Amount | | | |
| Al powder (4-6 μm) | 72.21 | 73.912 | 74.76 | 77.3 | 79 | 75.48 | 35.26 | 39.5 | 66 | 66 | 66 | 66 |
| Al powder (2 μm) | | | | | | | | | 12 | 12 | 12 | 12 |
| Al—Si Alloy | — | — | | — | | — | 37 | 37 | | | | |
| Powder | | | | | | | | | | | | |
| Glass Powder(s) | 0.8 | 1.1 | 1.25 | 1.7 | 2 | 1.5 | 1.25 | 1.25 | 1.25 | 1.25 | 1.25 | 1.25 |
| Ethoxide | 2.48 | 1.746 | 1.45 | 0.582 | 0 | 0 | 2.2 | 0 | 1.45 | 0.75 | 0.75 | 0.75 |
| Organometallic | | | | | | | | | | | | |
| (B, Ti) | | | | | | | | | | | | |
| Organometallic | 0 | 0 | 0 | 0 | 0 | 0 | 0 | 0 | 0 | 0.6 | 1.5 | 2.1 |
| Additive (Ni, V) | | | | | | | | | | | | |
| Total | 2.48 | 1.746 | 1.45 | 0.582 | 0 | 0 | 2.2 | 0 | 1.45 | 1.35 | 2.25 | 2.85 |
| Organometallic | | | | | | | | | | | | |
| Total Inorganic | 0.264 | 0.198 | 0.16 | 0.066 | 0 | 0 | 0.51 | 0.35 | 0.16 | 0.16 | 0.16 | 0.16 |
| Oxide Additives | | | | | | | | | | | | |
| (SiO2) | | | | | | | | | | | | |
| % Solids | 78 | 79 | 79 | 80 | 81 | 77 | 78 | 78 | 82 | 82 | 84 | 85 |
| % Vehicle | 22 | 21 | 21 | 20 | 19 | 23 | 22 | 22 | 18 | 18 | 16 | 15 |
| No of Glasses | 2 | 2 | 2 | 2 | 1 | 2 | 2 | 2 | 2 | 2 | 2 | 2 |
| Properties | | | | | | | | | | | | |
| Bulk Resistivity | 18.7 | 15.5 | 14 | 13.5 | 8.5 | 9.5 | 16.5 | 12 | 11 | 10.5 | 14 | 12 |
| (mΩ/sq/mil) | | | | | | | | | | | | |
| ReactionSeverity | 1 | 2 | 2.5 | 3 | 5 | 4 | 2 | 3 | 3 | 1.5 | 1.5 | 1 |
| (1 = low, 5 = High) | | | | | | | | | | | | |
| Adhesion on SiNx | <20 | | 30 | | >40 | 25 | 25 | 25 | 30 | 30 | 25 | 25 |
| BSF Thickness (μm) | 6.6 | | 5.9 | | 7.6 | 5.7 | 7.4 | 6.7 | 6.6 | 7.2 | 6 | 6.2 |
| Via Fill % | 50 | 50 | 70 | 50 | 50 | 80 | 50 | 100 | 70 | 70 | 60 | 65 |

Electrical Properties 900° C.

| | | | | | | | | |
|---|---|---|---|---|---|---|---|---|
| Jsc (mA/cm2) | 37.19 | 37.25 | 37.84 | 37.01 | 37.1 | 37.14 | 37 | 36.9 |
| Voc (mV) | 0.639 | 0.639 | 0.644 | 0.638 | 0.638 | 0.64 | 0.639 | 0.637 |
| FF(%) | 79.6 | 77.4 | 77.0 | 76.9 | 76.6 | 76.9 | 77.6 | 76.1 |
| EFF(%) | 18.2 | 18.4 | 18.8 | 18.1 | 18.1 | 18.3 | 18.3 | 17.9 |
| Rsc (Ohm-cm2) | 3478 | 5936 | 6955 | 5140 | 4770 | 4563 | 4345 | 5804 |
| Roc (Ohm-cm2) | 1.31 | 1.28 | 1.3 | 1.33 | 1.32 | 1.26 | 1.35 | |

Electrical Properties Temp = 880° C.

| | | | | | | | | | | | | |
|---|---|---|---|---|---|---|---|---|---|---|---|---|
| Jsc (mA/cm2) | 36.99 | 36.79 | 37.78 | 36.81 | 36.9 | 36.91 | 36.96 | 36.98 | | | | |
| Voc (mV) | 0.64 | 0.638 | 0.649 | 0.636 | 0.636 | 0.641 | 0.638 | 0.638 | | | | |
| FF(%) | 77.2 | 77.2 | 77.5 | 77.5 | 77.3 | 77.4 | 77.4 | 77.5 | | | | |
| EFF(%) | 18.3 | 18.1 | 19 | 18.1 | 18.1 | 18.3 | 18.3 | 18.3 | | | | |
| Rsc (Ohm-cm2) | 5422 | 5174 | 6998 | 5239 | 5380 | 3843 | 3560 | 6091 | | | | |
| Roc (Ohm-cm2) | 1.34 | 1.27 | 1.29 | 1.27 | 1.26 | 1.33 | 1.27 | 1.28 | | | | |
| % Glass AL77 | 50 | 27 | 20 | 6 | 0 | 33 | 20 | 20 | 20 | 20 | 20 | 20 |
| Organometallic-Ni | | | | | | | | | | | 1.5 | 1.5 |
| Organometallic - V | | | | | | | | | | 0.6 | | 0.6 |

TABLE 9
Best efficiency produced by the paste C on back surface
unpassivated cells (reference) and back surface passivated
(BSP) cells with rear local contact openings.

| | Jsc | Voc | Fill factor | Efficiency |
|---|---|---|---|---|
| Cell design | (mA/cm2) | (mV) | (%) | (%) |
| Conventional | 36.74 | 639 | 79.40 | 18.64 |
| Via geometry | 37.86 | 646 | 79.2 | 19.36 |

The gain in BSP cells over the reference cells is due to the enhanced J_{sc} and V_{oc} values. However, BSP cell show lower fill factors due to increased series resistance. The best group of BSP cells shows an average gain of 0.7% in conversion efficiencies over the reference cells.

What has been described above includes examples of the subject invention. It is, of course, not possible to describe every conceivable combination of components or methodologies for purposes of describing the subject invention, but one of ordinary skill in the art may recognize that many further combinations and permutations of the subject invention are possible. Accordingly, the subject invention is intended to embrace all such alterations, modifications and variations that fall within the spirit and scope of the appended claims. Furthermore, the foregoing ranges (e.g., compositional ranges and conditional ranges) are preferred and it is not the intention to be limited to these ranges where one of ordinary skill in the art would recognize that these ranges may vary depending upon specific applications, specific components and conditions for processing and forming the end products. Disclosure of a range constitutes disclosure of each discrete value within such range, and subranges within the range. One range can be combined with another range. Disclosure of a Markush group supports each individual member of such group and any subgrouping within such group. To the extent that the terms “contain,” “have,” “include,” and “involve” are used in either the detailed description or the claims, such terms are intended to be inclusive in a manner similar to the term “comprising” as “comprising” is interpreted when employed as a transitional word in a claim. In some instances, however, to the extent that the terms “contain,” “have,” “include,” and “involve” are used in either the detailed description or the claims, such terms are intended to be partially or entirely exclusive in a manner similar to the terms “consisting of” or “consisting essentially of” as “consisting of” or “consisting essentially of” are interpreted when employed as a transitional word in a claim.

1. A paste composition comprising, prior to firing:
a conductive metal component comprising aluminum;
a glass component;
a vehicle; and
at least one organometallic compound including an element selected from boron, silicon, vanadium, antimony, phosphorous, yttrium, titanium, nickel, cobalt, zirconium, zinc, lithium and combinations thereof.

2. (canceled)

3. The paste composition of claim 1, wherein the organometallic compound includes at least one C₁-C₅₀ organic moiety that is linear or branched, saturated or unsaturated, aliphatic, alicyclic, aromatic, araliphatic, halogenated or otherwise substituted, optionally having one or more heteroatoms such as O, N, S, or Si, and/or including hydrocarbon moieties such as alkyl, alkyloxy, alkoxide, alkylthio, or alkylsilyl moieties.

4. The paste composition of claim 1, wherein the organometallic compounds are selected from the group consisting of metal ethoxides, metal acetonates, metal acetylacetonates, metal carboxylates, metal 2-methylhexanoates, metal 2-ethylhexanoates, and metal 2-propylhexanoates, metal acrylates, metal methacrylates, and combinations thereof, wherein the metal is selected from the group consisting of titanium, zirconium, nickel, cobalt, zinc, vanadium, and combinations thereof.

5. (canceled)

6. The paste composition of claim 1, further comprising an Al—Si alloy, an Al—Si eutectic alloy, or both.

7. (canceled)

8. The paste composition of claim 1, wherein the conductive metal component further comprises up to 20 wt % of at least one of an Al—Si eutectic, zinc, tin, antimony, silicon, bismuth, indium, molybdenum, palladium, silver, platinum, gold, titanium, vanadium, nickel, copper, and combinations thereof, based upon 100% total weight of the paste composition.

9. The paste composition of claim 1, wherein the glass component includes at least one selected from the group consisting of (a) Bi—Zn based glasses, (b) borosilica glasses, (c) alkali-titanate glasses, (d) lead-glasses, and combinations thereof.

10. The paste composition of claim 1, wherein
the conductive metal component comprises about 40 to about 80 wt % of an aluminum source,
the glass component is present to an extent of about 0.1 to about 10 wt %, and
the vehicle is present to an extent of about 5 to about 30 wt %, all based upon 100% total weight of the paste composition.

11. The paste composition of claim 10, further comprising about 0.1 to about 10 wt % of an organic or inorganic additive compound.

12. The paste composition of claim 1, wherein the glass component comprises two or more glasses.

13. The paste composition of claim 1, wherein the D₅₀ particle size of the glass component is about 0.1 microns to about 20 microns.

14. The paste composition of claim 5, wherein the aluminum is provided in powder form having a bimodal particle size distribution, wherein a first D₅₀ average aluminum particle size is in the range of 0.5 to 3 microns and a second D₅₀ average aluminum particle size is 3-40 micron range, wherein no overlap is intended.

15. (canceled)

16. The paste composition of claim 1, wherein the viscosity of the paste is in the range of 5-80 Pa·s.

17. The paste composition of claim 1, wherein the metal component comprises both flake and spherical morphologies.

18. The paste composition of claim 1, wherein organic vehicle includes oleic acid, Duomeen TDO (tallowpropylene diamine dioleate) and DisperBYK® 111 (a copolymer with acidic groups having an acid value of 129 mg KOH/g, a density of 1.16 and a flash point over 100° C.).

19-31. (canceled)

32. A photovoltaic cell comprising a silicon wafer and a back contact thereon, the back contact comprising a passivation layer opened locally at least partially coated with a fired back side paste, the back side paste comprising, prior to firing:
a conductive metal component comprising aluminum;
a glass component;
a vehicle; and
at least one organometallic compound including an element selected from boron, silicon, vanadium, antimony, phosphorous, yttrium, titanium, nickel, cobalt, zirconium, zinc, lithium and combinations thereof.

33-39. (canceled)

40. A method of making a photovoltaic cell contact, comprising:
a. applying a paste composition to a locally opened rear passivation layer on a silicon substrate, the paste comprising a conductive metal component comprising aluminum, a glass component, a vehicle, and at least one of an organometallic additive compound, phosphate glass and phosphorus compound dispersed in the vehicle, wherein the organometallic compound is selected from boron, silicon, vanadium, antimony, phosphorous, yttrium, titanium, nickel, cobalt, zirconium, zinc, lithium and combinations thereof, wherein the organometallic compound can include C₁-C₅₀ organic moieties that are linear or branched, saturated or unsaturated, aliphatic, alicyclic, aromatic, araliphatic, halogenated or otherwise substituted, optionally having one or more heteroatoms such as O, N, S, or Si, and/or including hydrocarbon moieties such as alkyl, alkyloxy, alkoxide, alkylthio, or alkylsilyl moieties; and
b. heating the paste to sinter the conductive metal component.

41-43. (canceled)

44. The method of claim 40, wherein the passivation layer comprises at least one selected from the group consisting of SiNx, Al₂O₃, SiO₂, SiC, amorphous Si, TiO₂, Al₂O₃/SiNx, SiO₂/SiNx, SiO₂/Al₂O₃/SiNx in a combined thickness of about 5 to about 360 nm thick.

45. The method of claim 40, wherein the local openings are made by laser ablation or chemical etching using an etchant comprising phosphorus, to form dots or lines, wherein the dot diameter ranges from 20-200 microns and a trench is 100-700 microns wide, or the dot diameter ranges from 20-200 microns and a trench is 0.5-2.0 mm wide.

46-48. (canceled)
